(19) United States
(12) Patent Application Publication
(10) Pub. No.: US 2009/0101950 A1
(43) Pub. Date: Apr. 23, 2009

(54) CMOS IMAGE SENSOR AND METHOD FOR FABRICATING THE SAME

(75) Inventor: Joon HWANG, Cheongju-si (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/250,240

(22) Filed: Oct. 13, 2008

(30) Foreign Application Priority Data
Oct. 17, 2007 (KR) 10-2007-0104401

(51) Int. Cl. H01L 27/146; H01L 31/18

(52) U.S. Cl. 257/292; 438/70; 257/E27.133

(57) ABSTRACT

A CMOS image sensor and a method for fabricating the same. In one example embodiment, a method for fabricating a CMOS image sensor includes various steps. First, an interlayer dielectric that includes a plurality of metal lines is formed on a semiconductor substrate that includes a photodiode. Next, a trench is formed in the interlayer dielectric. Then, a passivation layer is formed in the trench. Next, the trench is filled by vapor-depositing an additional dielectric layer on the passivation layer. Then, a color filter is formed on the additional dielectric layer. Next, a planarization layer is formed on the color filter. Finally, a micro lens is formed on the planarization layer.

### CROSS-REFERENCE TO A RELATED APPLICATION

This application claims the benefit of Korean Patent Application No. 10-2007-0104401, filed on Oct. 17, 2007 which is hereby incorporated by reference as if fully set forth herein.

### BACKGROUND

1. Field of the Invention

Embodiments of the present invention relate to a semiconductor device, and more particularly, to a complementary metal oxide semiconductor (CMOS) image sensor and a method for fabricating the same.

2. Description of the Related Art

Image sensors, used to convert optical images into electrical signals, can be generally classified into two types: complementary metal oxide semiconductors (CMOSs) and charge coupled devices (CCDs). CMOS image sensors apply a switching method that produces metal oxide semiconductor (MOS) transistors corresponding to the number of pixels and detect outputs using the MOS transistors. CMOS image sensors are advantageous in various aspects compared to CCD image sensors. For example, CMOS image sensors are more convenient in operation and capable of applying a variety of scanning methods and achieving a compact-sized product since signal-processing circuits can be integrated on a single chip. Furthermore, fabrication cost can be reduced by using a compatible CMOS technology, and power consumption can also be considerably reduced. As a result, use of CMOS image sensors is increasing.

A CMOS image sensor of 0.18 μm requires a logic device comprising a sensor driver having a 4-layer line structure. More specifically, the logic device also requires three layers of an inter-metal dielectric (IMD) and one layer of an interlayer dielectric (ILD) as well as the 4-layer line structure. Problems associated with prior art CMOS image sensors will now be explained with reference to FIG. 1.

FIG. 1 is a sectional view schematically showing the structure of a prior art CMOS image sensor. As shown in FIG. 1, the prior art CMOS image sensor includes a semiconductor substrate 1, an interlayer dielectric 4 formed on the semiconductor substrate 1, a passivation layer 6 formed on the interlayer dielectric 4, a color filter 7 formed on the interlayer dielectric 4, a planarization layer 8 formed on the color filter 7, and a micro lens 9 formed on the planarization layer 8. The semiconductor substrate 1 includes a device isolation layer 2 and a photodiode 3. The interlayer dielectric 4 includes a plurality of metal lines 5a, 5b, and 5c.

As shown in FIG. 1, the metal lines 5a, 5b, and 5c have a multilayer structure that increases thickness of the interlayer dielectric 4 disposed between the micro lens 9 and the photodiode 3. This increased thickness hinders the focusing of light transmitted through the micro lens 9. Attempts to improve the focusing of light have included reducing the curvature of the micro lens 9. However, these attempts have proven ineffective and the deterioration of light transmission from the micro lens 9 to the photodiode 3 has not been adequately resolved. Moreover, since the light is focused on an upper part of the photodiode 3, there is deterioration in the light sensitivity in the prior art CMOS image sensor. Also, defects such as cross-talk among pixels are caused by irregular diffusion and reflection of incident light.

### SUMMARY OF EXAMPLE EMBODIMENTS

In general, example embodiments of the present invention relate to a complementary metal oxide semiconductor (CMOS) image sensor and methods for fabricating the same. Some example embodiments are capable of improving light sensitivity by adding a material having a relatively high light guiding property to an interlayer dielectric at a position where light is transmitted from a micro lens to a photodiode. Some example embodiments also reduce cross-talk.

In one example embodiment, a method for fabricating a CMOS image sensor includes various steps. First, an interlayer dielectric that includes a plurality of metal lines is formed on a semiconductor substrate that includes a photodiode. Next, a trench is formed in the interlayer dielectric. Then, a passivation layer is formed in the trench. Next, the trench is filled by vapor-depositing an additional dielectric layer on the passivation layer. Then, a color filter is formed on the additional dielectric layer. Next, a planarization layer is formed on the color filter. Finally, a micro lens is formed on the planarization layer.

In another example embodiment, a CMOS image sensor includes a semiconductor substrate that includes a photodiode and an interlayer dielectric formed on the semiconductor substrate. The interlayer dielectric includes a plurality of metal lines and a trench disposed corresponding to a light path to the photodiode. The CMOS image sensor also includes a passivation layer formed in the trench, an additional dielectric layer filling in the trench, a color filter formed on the additional dielectric layer, a planarization layer formed on the color filter, and a micro lens formed on the planarization layer.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of example embodiments of the invention and are incorporated in and constitute a part of this application, illustrate example embodiments of the invention. In the drawings:

FIG. 1 is a sectional view schematically showing the structure of a prior art CMOS image sensor; and

FIG. 2A through FIG. 2C are sectional views showing the structure of an example CMOS image sensor.

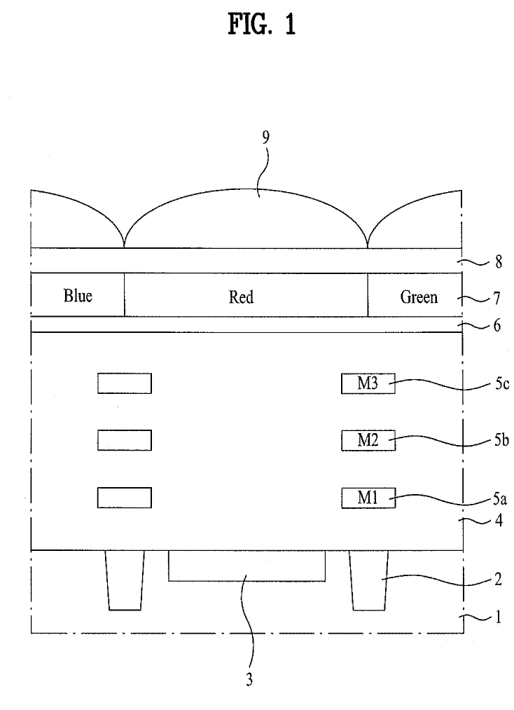

### DETAILED DESCRIPTION OF EXAMPLE EMBODIMENTS

In the following detailed description of the embodiments, reference will now be made in detail to specific embodiments of the present invention, examples of which are illustrated in the accompanying drawings. Wherever possible, the same reference numbers will be used throughout the drawings to refer to the same or like parts. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

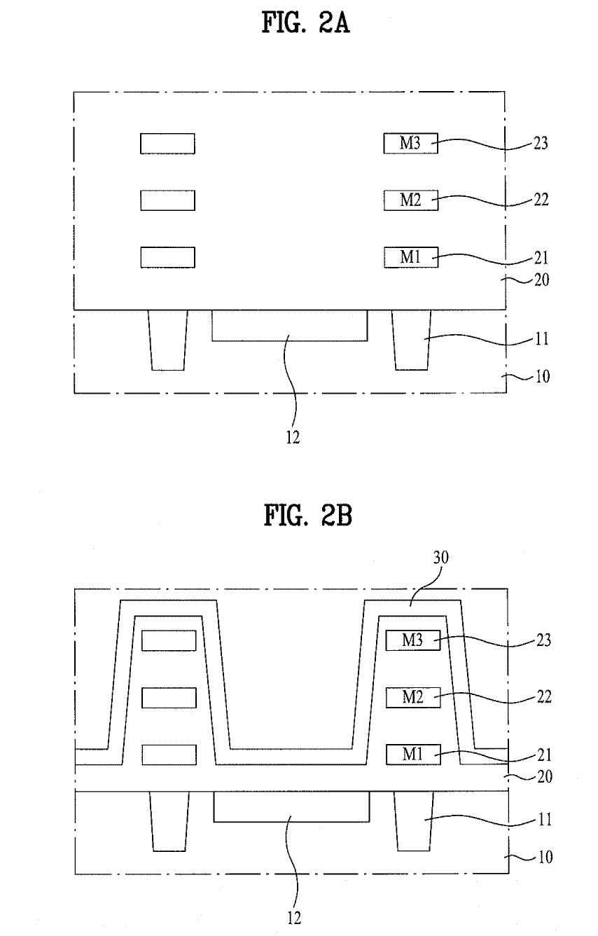

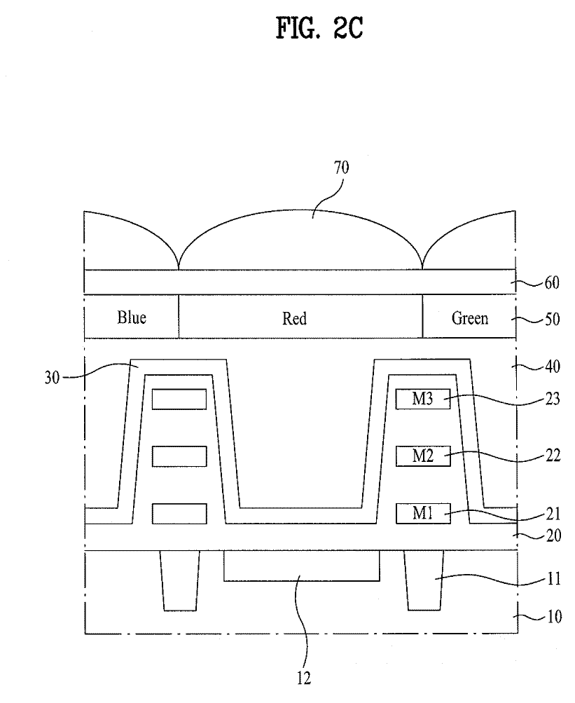

FIG. 2A through FIG. 2C are sectional views showing the structure of an example complementary metal oxide semiconductor (CMOS) image sensor. As disclosed in FIG. 2A, the example CMOS image sensor is fabricated by first, forming an interlayer dielectric 20 that includes a plurality of metal lines 21, 22, and 23 on a semiconductor substrate 10. The semiconductor substrate 10 includes a device isolation layer 11 and a photodiode 12. The interlayer dielectric 20 may be formed, for example, from an undoped silicate glass (USG) layer, a fluorine doped silicate glass (FUSG) layer, or some combination thereof.

The metal lines 21, 22, and 23 formed in the interlayer dielectric 20 include a metal line for driving the image sensor and a metal line for driving a logic circuit. The metal lines 21, 22, and 23 can be formed in multiple layers, for example, between about 2 and about 5 layers. More specifically, a series of processes including vapor-deposition of USG, planarization, vapor-deposition of a nitride layer, annealing and removal of the nitride layer are repeated while forming the multilayered metal lines 21, 22, and 23 in the interlayer dielectric 20.

Next, with reference now to FIG. 2B, a photoresist pattern (not shown) is formed on the interlayer dielectric 20. The interlayer dielectric 20 is then partially etched using the photoresist pattern as an etching mask, thereby forming a trench at a position where light is transmitted to the photodiode 12. The depth of the trench may be the same as or greater than the thickness of an additional dielectric layer that will be formed later, as discussed below. In a case where the trench has greater depth than the additional dielectric layer, the thickness of a passivation layer 30 formed in the trench, as discussed below, may also be considered to be a part of the thickness of the additional dielectric layer. During the etching for forming the trench, the photoresist pattern may also be simultaneously etched and thereby removed.

Next, a passivation layer 30 is formed on the whole surface of the interlayer dielectric 20, including within the trench formed in the interlayer dielectric 20. The passivation layer 30 can be manufactured in the form of a liner, by vapor-depositing a silicon nitride layer through plasma-enhanced chemical vapor deposition (PECVD). After the passivation layer 30 is formed, annealing may be performed with respect to the semiconductor substrate 10 so as to cure the passivation layer 30.

With reference now to FIG. 2C, an additional dielectric layer 40 is next vapor-deposited on the whole surface of the passivation layer 30, thereby filling the trench formed in the interlayer dielectric 20. The additional dielectric layer 40 may have higher refractivity than the interlayer dielectric 20. Also, the additional dielectric layer 40 may be formed of a dielectric material having a higher light guiding property than the interlayer dielectric 20. After formation of the additional dielectric layer 40, spin coating may be performed with respect to a surface of the additional dielectric layer 40 in order to planarize the surface of the additional dielectric layer 40.

Next, a resist for a color filter is applied on the additional dielectric layer 40, and then color filter layers are formed. In this embodiment, the color filter 50 includes three colors, red (R), green (G), and blue (B) and is formed by performing color filter manufacturing processes multiple times. The R, G and B color filters 50 are stepped with respect to one another in accordance with their respective resist properties.

A planarization layer 60, made of silicon nitride for example, is next formed to compensate for the height difference of the color filter 50. In addition, a resist pattern for forming a micro lens 70 is formed on the planarization layer 60. A micro lens resist pattern is next formed by applying a resist for the micro lens 70 on the planarization layer 60 and performing photolithography with the resist. Then, annealing is performed with respect to the micro lens resist pattern so that the micro lens resist pattern reflows. As a result, the micro lens 70 having a dome shape is formed.

As describe above, is some embodiments of the present invention, the trench is formed at the position where the light is transmitted from the micro lens 70 to the photodiode 12. Then a dielectric material having a higher light guiding property than the interlayer dielectric is applied to fill the trench. This structure results in improved light condensing efficiency and light sensitivity of the image sensor, while also reducing cross-talk in the color filter.

Although example embodiments of the present invention have been shown and described, changes might be made to these example embodiments. The scope of the invention is therefore defined in the following claims and their equivalents.

What is claimed is:

1. A method for fabricating a complementary metal oxide semiconductor (CMOS) image sensor, comprising:
forming an interlayer dielectric that includes a plurality of metal lines on a semiconductor substrate that includes a photodiode;
forming a trench in the interlayer dielectric;
forming a passivation layer in the trench;
filling the trench by vapor-depositing an additional dielectric layer on the passivation layer;
forming a color filter on the additional dielectric layer;
forming a planarization layer on the color filter; and
forming a micro lens on the planarization layer.

2. The method as recited in claim 1, wherein forming a trench in the interlayer dielectric comprises:
forming a photoresist pattern on the interlayer dielectric; and
partially etching the interlayer dielectric to form the trench using the photoresist pattern as an etching mask.

3. The method as recited in claim 1, wherein the interlayer dielectric comprises an undoped silicate glass (USG) layer, a fluorine doped silicate glass (FUSG) layer, or some combination thereof.

4. The method as recited in claim 1, wherein the passivation layer is formed by vapor-depositing a silicon nitride layer through plasma-enhanced chemical vapor deposition (PECVD).

5. The method as recited in claim 1, further comprising annealing the semiconductor substrate after the passivation layer is formed.

6. The method as recited in claim 1, wherein the additional dielectric layer comprises a dielectric material having a higher light guiding property than the interlayer dielectric.

7. The method as recited in claim 1, wherein the additional dielectric layer comprises a material having higher refractivity than the interlayer dielectric.

8. The method as recited in claim 1, wherein the additional dielectric layer is formed by vapor-depositing a silicon nitride layer through PECVD.

9. The method as recited in claim 8, further comprising planarizing the additional dielectric layer through spin coating after the additional dielectric layer is vapor-deposited.

10. The method as recited in claim 1, wherein the trench is disposed at a position on the interlayer dielectric where light is transmitted to the photodiode.

11. A CMOS image sensor comprising:
a semiconductor substrate that includes a photodiode;
an interlayer dielectric formed on the semiconductor substrate, the interlayer dielectric including a plurality of metal lines and a trench disposed corresponding to a light path to the photodiode;
a passivation layer formed in the trench;
an additional dielectric layer filling in the trench;
a color filter formed on the additional dielectric layer;
a planarization layer formed on the color filter; and
a micro lens formed on the planarization layer.

12. The CMOS image sensor as recited in claim 11, wherein the interlayer dielectric comprises a USG layer, an FUSG layer, or some combination thereof.

13. The CMOS image sensor according to claim 11, wherein the passivation layer is formed by vapor-depositing a silicon nitride layer through PECVD.

14. The CMOS image sensor according to claim 11, wherein the additional dielectric layer comprises a dielectric material having a higher light guiding property than the interlayer dielectric.

15. The CMOS image sensor according to claim 11, wherein the additional dielectric layer is formed of a material having higher refractivity than the interlayer dielectric.

16. The CMOS image sensor according to claim 11, wherein the additional dielectric layer is formed by vapor-depositing a silicon nitride layer through PECVD.
